(19) United States
(12) Patent Application Publication
(10) Pub. No.: US 2026/0334159 A1
(43) Pub. Date: Oct. 22, 2026

(54) SEMICONDUCTOR DEVICE STACK AND METHOD FOR FABRICATING THE SAME

(71) Applicant: NANYA TECHNOLOGY CORPORATION, NEW TAIPEI CITY (TW)

(72) Inventor: SHENG-FU HUANG, NEW TAIPEI CITY (TW)

(21) Appl. No.: 19/236,152

(22) Filed: Jun. 12, 2025

Related U.S. Application Data
(63) Continuation of application No. 19/185,509, filed on Apr. 22, 2025.

(51) Int. Cl. H01L 21/683; H01L 23/00; H01L 23/15; H01L 23/48; H01L 25/07

(52) U.S. Cl. CPC H10P 72/7402; H10W 20/20; H10W 70/692; H10W 90/00; H10P 72/7432; H10W 72/325; H10W 72/354; H10W 90/26; H10W 90/297; H10W 90/734; H10W 90/792

(57) ABSTRACT

The present application discloses a semiconductor device stack and a method for fabricating the semiconductor device stack. The semiconductor device stack includes a bottom device layer, at least one intermediate device layer, and a surface device layer sequentially stacked; through substrate vias respectively positioned in the device layers; inter-layered connection vias electrically connecting the through substrate vias and the device layers, respectively; a first carrier contacting the back side of the bottom device layer and covering the bottom through substrate via; and a second carrier covering a front side of the surface device layer.

### CROSS-REFERENCE TO RELATED APPLICATION

This application is a continuation application of U.S. Non-Provisional application Ser. No. 19/185,509 filed Apr. 22, 2025, which is incorporated herein by reference in its entirety.

### TECHNICAL FIELD

The present disclosure relates to a semiconductor device stack and a method for fabricating the semiconductor device stack, and more particularly, to a semiconductor device stack including multiple carriers.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device stack including a bottom device layer, at least one intermediate device layer, and a surface device layer sequentially stacked; a bottom through substrate via positioned in the bottom device layer and a bottom surface of the bottom through substrate via is coplanar with a back side of the bottom device layer; at least one intermediate through substrate via positioned in the at least one intermediate device layer and a bottom surface of the at least one intermediate through substrate via is coplanar with a back side of the at least one intermediate device layer contacting the bottom device layer; a surface through substrate via positioned in the surface device layer and a bottom surface of the surface through substrate via is coplanar with a back side of the surface device layer contacting the at least one intermediate device layer; a plurality of inter-layered connection vias electrically connecting the bottom through substrate via and the at least one intermediate device layer, and electrically connecting the surface through substrate via and the at least one intermediate device layer, respectively; a first carrier contacting the back side of the bottom device layer and covering the bottom through substrate via; and a second carrier covering a front side of the surface device layer.

Another aspect of the present disclosure provides a semiconductor device stack including a bottom device layer, at least one intermediate device layer, and a surface device layer sequentially stacked; a bottom through substrate via positioned in the bottom device layer and a bottom surface of the bottom through substrate via is coplanar with a back side of the bottom device layer; at least one intermediate through substrate via positioned in the at least one intermediate device layer and a bottom surface of the at least one intermediate through substrate via is coplanar with a back side of the at least one intermediate device layer contacting the bottom device layer; a surface through substrate via positioned in the surface device layer and a bottom surface of the surface through substrate via is coplanar with a back side of the surface device layer contacting the at least one intermediate device layer; a plurality of inter-layered connection vias electrically connecting the bottom through substrate via and the at least one intermediate device layer, and electrically connecting the surface through substrate via and the at least one intermediate device layer, respectively; a front side of a functional device layer positioned on the back side of the bottom device layer; and a second carrier covering a front side of the surface device layer.

Another aspect of the present disclosure provides a method for fabricating a semiconductor device stack including providing an intermediate stack including a bottom device layer, at least one intermediate device layer, and a surface device layer sequentially stacked, and a bottom through substrate via in the bottom device layer, wherein a bottom surface of the bottom through substrate via is coplanar with a back side of the bottom device layer; forming a first carrier covering the back side of the bottom device layer and the bottom surface of the bottom through substrate via; performing a chip probing process through an opening of the surface device layer and filling the opening; forming a second carrier covering a front side of the surface device layer; separating the intermediate stack from the first carrier; and flipping the intermediate stack and bonding a functional device layer onto the back side of the bottom device layer.

Due to the design of the semiconductor device stack of the present disclosure, the induced parasitic inductance arising from dangling (or floating) bottom through substrate via may be avoided by bonding the functional device layer onto the bottom through substrate via with the support of the second carrier. As a result, the performance of the semiconductor device stack may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device stack in accordance with one embodiment of the present disclosure;

FIG. 2 illustrates, in a schematic cross-sectional view diagram, an intermediate stage for fabricating the semiconductor device stack in accordance with one embodiment of the present disclosure;

FIG. 3 illustrates, in a schematic close-up diagram, a through substrate via in accordance with one embodiment of the present disclosure;

FIGS. 4 to 8 illustrate, in schematic close-up diagrams, first adhesive structures in accordance with some embodiment of the present disclosure;

FIGS. 9 and 10 illustrate, in schematic cross-sectional view diagrams, intermediate stages for fabricating the semiconductor device stack in accordance with one embodiment of the present disclosure;

FIGS. 11 to 16 illustrate, in schematic close-up diagrams, second adhesive structures in accordance with some embodiment of the present disclosure; and

FIGS. 17 to 19 illustrate, in schematic cross-sectional view diagrams, intermediate stages for fabricating the semiconductor device stack 1 in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

It should be noted that, in the description of the present disclosure, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

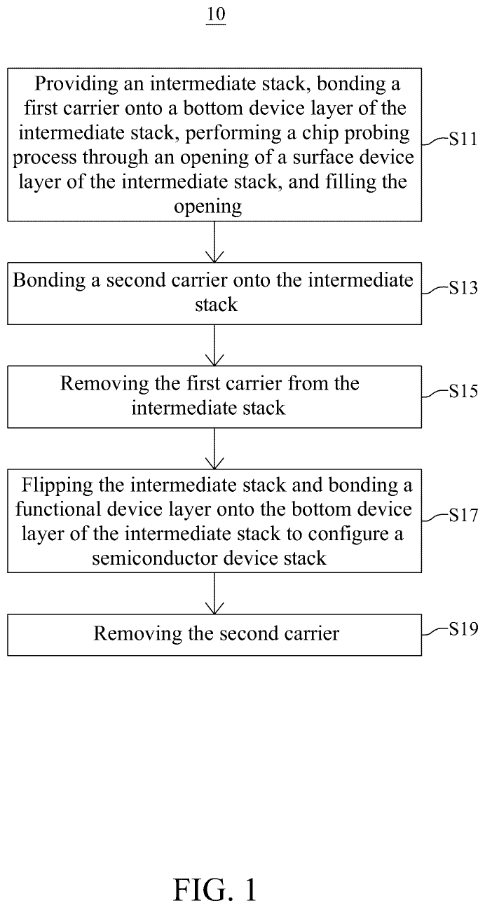

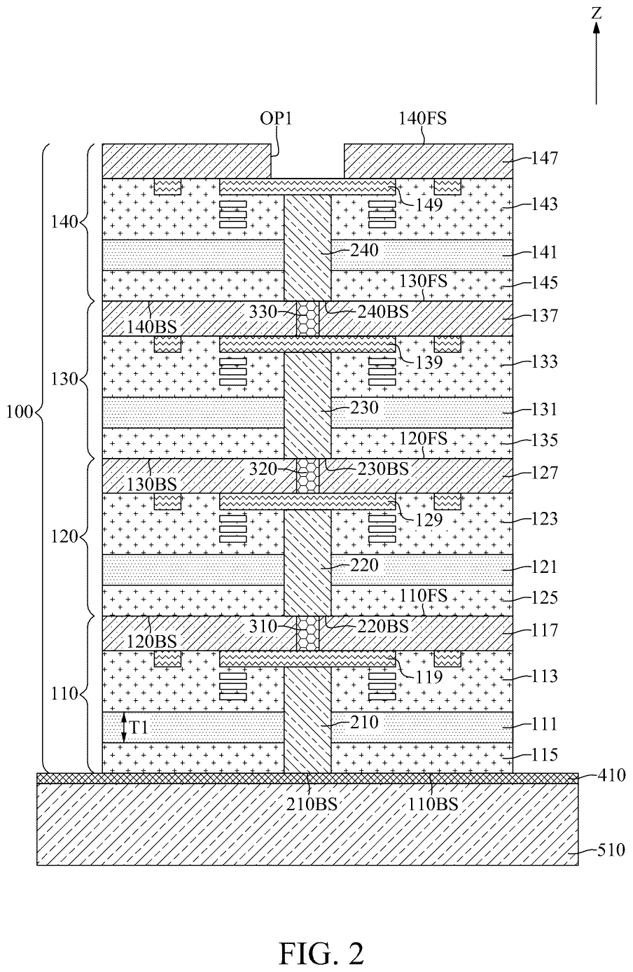

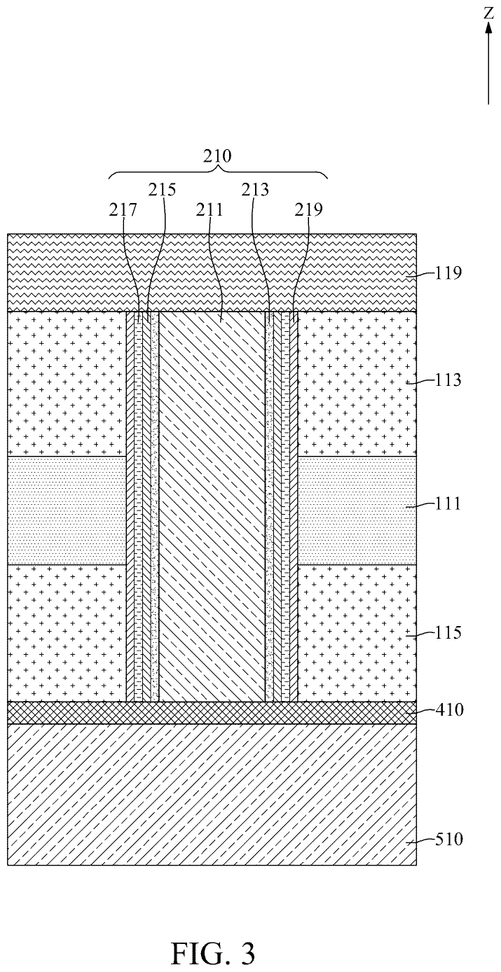

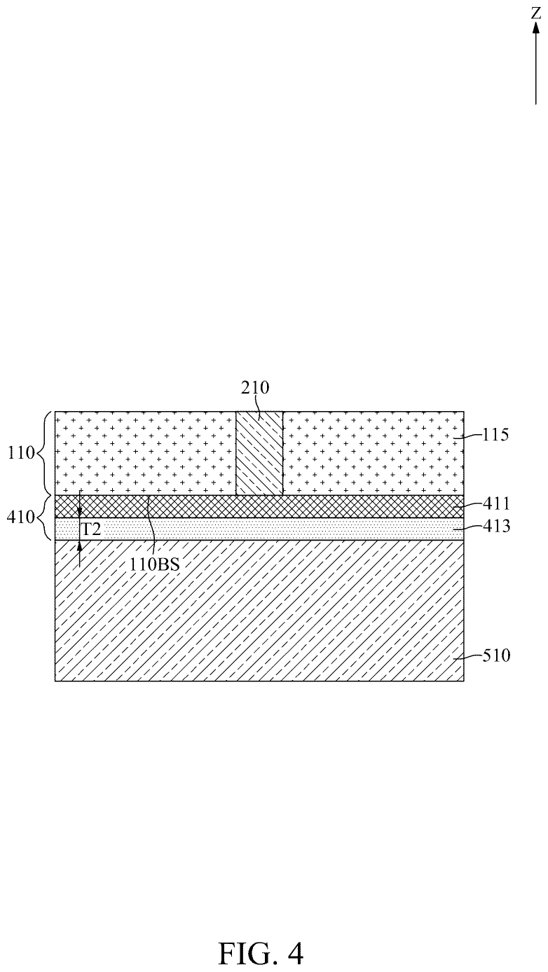

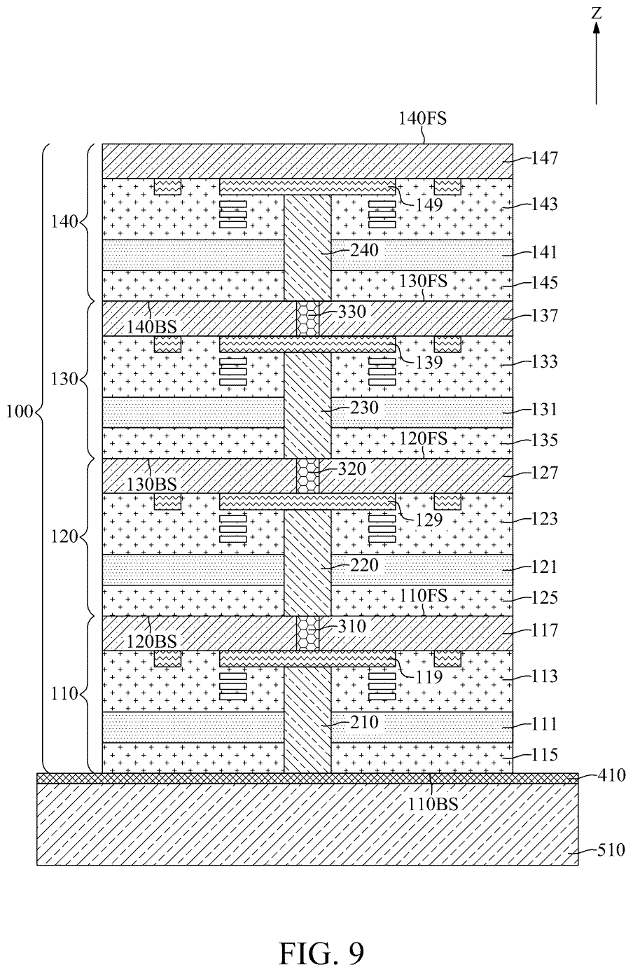

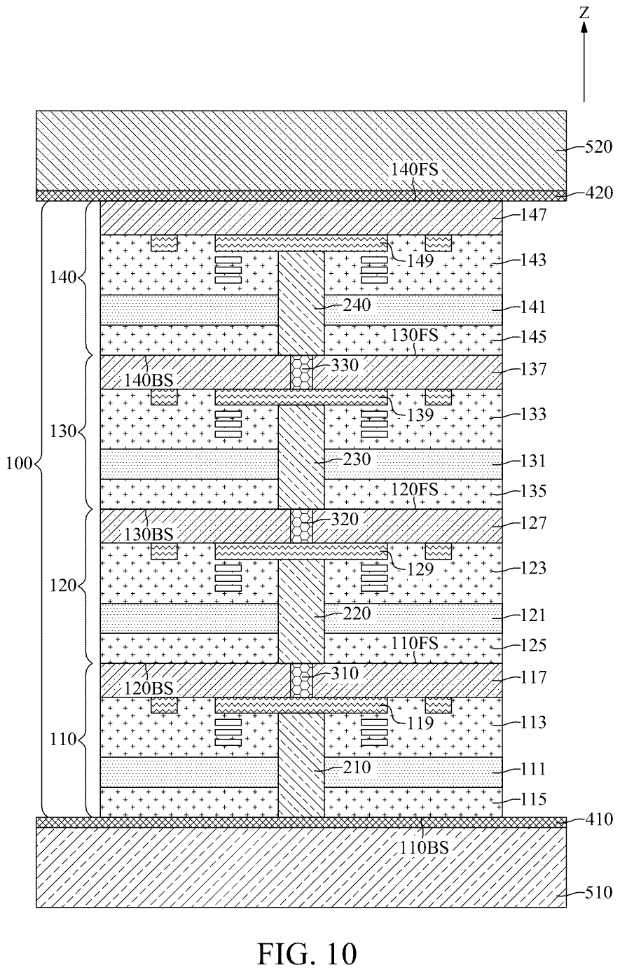

FIG. 1 illustrates, in a flowchart diagram form, a method 10 for fabricating a semiconductor device stack 1 in accordance with one embodiment of the present disclosure. FIG. 2 illustrates, in a schematic cross-sectional view diagram, an intermediate stage for fabricating the semiconductor device stack 1 in accordance with one embodiment of the present disclosure. FIG. 3 illustrates, in a schematic close-up diagram, a through substrate via in accordance with one embodiment of the present disclosure. FIGS. 4 to 8 illustrate, in schematic close-up diagrams, first adhesive structures in accordance with some embodiment of the present disclosure. FIGS. 9 and 10 illustrate, in schematic cross-sectional view diagrams, intermediate stages for fabricating the semiconductor device stack 1 in accordance with one embodiment of the present disclosure.

With reference to FIGS. 1 to 9, at step S11, an intermediate stack 100 may be provided, a first carrier 510 may be bonded onto a bottom device layer 110 of the intermediate stack 100, a chip probing process may be performed through an opening OP1 of a surface device layer 140 of the intermediate stack 100, and the opening OP1 may be filled.

With reference to FIG. 2, the semiconductor device stack 1 may include the bottom device layer 110, at least one intermediate device layer, and the surface device layer 140. In the present embodiment, two intermediate device layers 120, 130 may be employed as an example. The number of the intermediate device layers can be more or less. In some embodiments, the bottom device layer 110, the intermediate device layer 120, the intermediate device layer 130, and the surface device layer 140 may be sequentially stacked along the Z direction.

Detailedly, the bottom device layer 110 may include a back side 110BS and a front side 110FS. The back side 110BS may be faced downward, while the front side 110FS may be parallel, opposite to the back side 110BS, and face upward. The intermediate device layer 120 may include a back side 120BS and a front side 120FS, where the back side 120BS may be substantially coplanar with and in contact with the front side 110FS. The back side 120BS may be faced downward and contact the front side 110FS. The front side 120FS may be parallel to the back side 120BS, opposite to the back side 120BS, and faced in the same direction as the front side 110FS. Similarly, the intermediate device layer 130 may include a back side 130BS and a front side 130FS, where the back side 130BS may be substantially coplanar with and in contact with the front side 120FS. The front side 130FS may be parallel to the back side 130BS, opposite to the back side 130BS, and face upward. The surface device layer 140 may include a back side 140BS and a front side 140FS, where the back side 140BS may be substantially coplanar with and in contact with the front side 130FS. The front side 140FS may be parallel to the back side 140BS, opposite to the back side 140BS, and face away from the back side 140BS.

In some embodiments, the bottom device layer 110 may include a substrate 111, a plurality of device elements (not show for clarity), a dielectric layer 113, a back side covering layer 115, a passivation layer 117, and a plurality of conductive features 119.

In some embodiments, the substrate 111 may include a bulk semiconductor substrate that is composed entirely of at least one semiconductor material. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the thickness T1 of the substrate 111 may be less than about 200 μm, less than about 50 μm, or less than about 10 μm. For example, the thickness T1 of the substrate 111 may be about 3 μm. It should be noted that, in the description of present disclosure, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

In some embodiments, the plurality of device elements may be formed on the bulk semiconductor substrate. Some portions of the plurality of device elements may be formed in the bulk semiconductor substrate. The plurality of device elements may be transistors such as complementary metal-oxide-semiconductor transistors, metal-oxide-semiconductor field-effect transistors, fin field-effect-transistors, the like, or a combination thereof.

In some embodiments, the dielectric layer 113 may be disposed on the substrate 111. In some embodiments, the dielectric layer 113 may be a stacked layer structure. The dielectric layer 113 may include a plurality of insulating sub-layers. Each of the plurality of insulating sub-layers may have a thickness between about 0.5 micrometer and about 3.0 micrometer. The plurality of insulating sub-layers may be formed of, for example, silicon oxide, borophosphosilicate glass, undoped silicate glass, fluorinated silicate glass, low-k dielectric materials, the like, or a combination thereof. The plurality of insulating sub-layers may be formed of different materials but is not limited thereto. The low-k dielectric materials may have a dielectric constant less than 3.0 or even less than 2.5. In some embodiments, the low-k dielectric materials may have a dielectric constant less than 2.0. The plurality of insulating sub-layers may be formed by deposition processes such as chemical vapor deposition, plasma-enhanced chemical vapor deposition, or the like. Planarization processes may be performed after the deposition processes to remove excess material and provide a substantially flat surface for subsequent processing steps.

In some embodiments, the plurality of conductive features 119 may be disposed in the dielectric layer 113. The plurality of conductive features 119 may include interconnect layers, conductive vias, and a plurality of conductive pads. The interconnect layers may be separated from each other and may be horizontally disposed in the plurality of dielectric layers along the Z direction. The topmost interconnect layers may be designated as the conductive pads. The top surfaces of the conductive pads and the top surface of the dielectric layer 113 may be substantially coplanar. The conductive vias may connect adjacent interconnect layers, adjacent device element and interconnect layer, and adjacent conductive pad and interconnect layer along the Z direction. In some embodiments, the conductive vias may improve heat dissipation and may provide structure support. In some embodiments, the plurality of conductive features may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The plurality of conductive features 119 may be formed during the formation of the dielectric layer 113.

In some embodiments, the plurality of device elements and the plurality of conductive features 119 may together configure functional units of the bottom device layer 110. A functional unit, in the description of the present disclosure, generally refers to functionally related circuitry that has been partitioned for functional purposes into a distinct unit. In some embodiments, functional units may be typically highly complex circuits such as page buffers, decoders, sense amplifiers, drivers, charge pumps, current or voltage references, or any active or passive components of the circuits such as transistors, diodes, resistors, or capacitors. In some other embodiments, the complexity and functionality of a functional unit may be more or less complex. For example, the functional units may be memory strings intersecting with conductor layers.

In some embodiments, the back side covering layer 115 may be disposed under the substrate 111 to protect the back side of the substrate 111 during manufacturing. In some embodiments, the back side covering layer 115 may be formed of, silicon nitride, silicon carbon nitride, or other applicable insulating materials. In the present embodiment, the bottom surface of the back side covering layer 115 may be referred to as the back side 110BS of the bottom device layer 110. In some embodiments, the back side covering layer 115 may be optional. In such a situation, the bottom surface of the substrate 111 may be referred to as the back side 110BS of the bottom device layer 110.

In some embodiments, the passivation layer 117 may be disposed on the dielectric layer 113. In some embodiments, the passivation layer 117 may be formed of, for example, silicon oxide, silicon nitride, or other applicable dielectric material. The passivation layer 117 may be formed by, for example, chemical vapor deposition or other applicable deposition processes. The passivation layer 117 may serve as a protective or buffer layer, preventing the topmost conductive features 119 of the bottom device layer 110 from being exposed or damaged during subsequent semiconductor processing steps.

In some embodiments, the intermediate device layer 120 may have the same or a similar layout (or design) as the bottom device layer 110. Elements such as the substrate 121, dielectric layer 123, passivation layer 127, and conductive features 129 may be formed from the same materials and arranged in the same manner as their counterparts in the bottom device layer 110; therefore, their descriptions are not repeated herein.

In some embodiments, the intermediate device layer 130 may have the same or a similar layout (or design) as the bottom device layer 110. Elements such as the substrate 131, dielectric layer 133, passivation layer 137, and conductive features 139 may be formed from the same materials and arranged in the same manner as their counterparts in the bottom device layer 110; therefore, their descriptions are not repeated herein.

In some embodiments, the surface device layer 140 may have the same or a similar layout (or design) as the bottom device layer 110. Elements such as the substrate 141, dielectric layer 143, passivation layer 147, and conductive features 149 may be formed from the same materials and arranged in the same manner as their counterparts in the bottom device layer 110; therefore, their descriptions are not repeated herein.

With reference to FIGS. 2 and 3, a bottom through substrate via 210 may be formed penetrating the substrate 111 and the back side covering layer 115, and extending to the dielectric layer 113 and electrically connecting the topmost corresponding conductive feature 119. The bottom surface 210BS of the bottom through substrate via 210 may be substantially coplanar with the back side 110BS of the bottom device layer 110. In some embodiments, the bottom through substrate via 210 may include a conductive filler layer 211, a seed layer 213, an adhesion layer 215, a barrier layer 217, and an isolation layer 219.

In some embodiments, the conductive filler layer 211 may be disposed penetrating the substrate 111 and the back side covering layer 115, extending to the dielectric layer 113, and electrically connecting the topmost corresponding conductive feature 119. The conductive filler layer 211 may be formed of, for example, polysilicon, tungsten, copper, carbon nanotube, or solder alloy.

In some embodiments, the seed layer 213 may be disposed on the sidewalls of the conductive filler layer 211. The seed layer 213 may have a thickness between about 10 nm and about 40 nm. The seed layer 213 may be formed of, for example, copper. The seed layer 213 may reduce the resistivity of an opening during the formation of the conductive filler layer 211.

In some embodiments, the adhesion layer 215 may be disposed on the sidewalls of the seed layer 213. The adhesion layer 215 may be formed of, for example, titanium, tantalum, titanium tungsten, or manganese nitride. The adhesion layer 215 may improve an adhesion between the seed layer 213 and the barrier layer 217.

In some embodiments, the barrier layer 217 may be disposed on the sidewalls of the adhesion layer 215. The barrier layer 217 may be formed of, for example, tantalum, tantalum nitride, titanium, titanium nitride, rhenium, nickel boride, or tantalum nitride/tantalum bilayer. The barrier layer 217 may inhibit diffusion of the conductive materials of the conductive filler layer 211 into adjacent dielectric layers or substrate (e.g., the dielectric layer 113, the back side covering layer 115, and/or the substrate 111).

In some embodiments, the isolation layer 219 may be formed on the sidewalls of the barrier layer 217. The isolation layer 219 may electrically isolate the conductive filler layer 211 from adjacent dielectric layers or substrate (e.g., the dielectric layer 113, the back side covering layer 115, and/or the substrate 111).

An intermediate through substrate via 220 may be disposed in the intermediate device layer 120. The bottom surface 220BS of the intermediate through substrate via 220 may be substantially coplanar with the back side 120BS of the intermediate device layer 120. An intermediate through substrate via 230 may be disposed in the intermediate device layer 130. The bottom surface 230BS of the intermediate through substrate via 230 may be substantially coplanar with the back side 130BS of the intermediate device layer 130. A surface through substrate via 240 may be disposed in the surface device layer 140. The bottom surface 240BS of the surface through substrate via 240 may be substantially coplanar with the back side 140BS of the surface device layer 140.

The intermediate through-substrate via 220, the intermediate through-substrate via 230, and the surface through-substrate via 240 may have the same or similar structures and functions as those described for the bottom through-substrate via 210; therefore, detailed descriptions are not repeated herein.

With reference back to FIG. 2, an inter-layered connection via 310 may be formed in the passivation layer 117 to electrically connect the intermediate through substrate via 220 and the corresponding conductive feature 119 of the bottom device layer 110. An inter-layered connection via 320 may be formed in the passivation layer 127 to electrically connect the intermediate through substrate via 230 and the corresponding conductive feature 129 of the intermediate device layer 120. An inter-layered connection via 330 may be formed in the passivation layer 137 to electrically connect the surface through substrate via 240 and the corresponding conductive feature 139 of the bottom device layer 130.

In some embodiments, the plurality of inter-layered connection vias 310, 320, 330 may be formed of, for example, tungsten, cobalt, zirconium, tantalum, titanium, aluminum, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference back to FIG. 2, the first carrier 510 may be bonded beneath the intermediate stack 100. In some embodiments, the first carrier 510 may be a dummy wafer. A dummy wafer is a type of wafer used for temporary support of structures attached to it and does not include any permanently integrated functional units. The dummy wafer may be formed from materials such as silicon, glass, polymer, sapphire, or other suitable substrates. In some embodiments, the first carrier 510 may also be a thick dielectric layer that can be removed by grinding in subsequent processes. This dielectric layer may include materials such as silicon oxide, borophosphosilicate glass, undoped silicate glass, fluorinated silicate glass, silicon nitride, silicon oxynitride, silicon nitride oxide, or other appropriate dielectric materials. In some embodiments, the thickness of the dielectric layer may be greater than 500 μm.

In some embodiments, the first carrier 510 may be bonded onto the back side 110BS of the bottom device layer 110 via a first adhesive structure 410 formed therebetween. In some embodiments, the first adhesive structure 410 may include materials that are resistant to acids, alkalis, and high temperatures to ensure stability during backside processes such as curing, grinding, etching, and metallization, prior to debonding the intermediate stack 100 from the first carrier 510.

With reference to FIGS. 2 and 4, the first adhesive structure 410 may be disposed between the first carrier 510 and the bottom device layer 110. In some embodiments, the first adhesive structure 410 may include a first adhesive layer 411 and a first releasing layer 413. The first releasing layer 413 may directly contact the first carrier 510, meaning it is disposed on the first carrier 510. The first adhesive layer 411 may directly contact the back side 110BS of the bottom device layer 110 and between the first releasing layer 413 and the bottom device layer 110, meaning it is disposed under the bottom device layer 110.

In some embodiments, the first releasing layer 413 may be removed during a subsequent process via thermal slide debonding, chemical dissolution, mechanical peel-off, or laser ablation, thereby enabling debonding of the bottom device layer 110 from the first carrier 510.

In some embodiments, where the debonding of the bottom device layer 110 from the first carrier 510 is achieved by laser ablation, the first releasing layer 413 may be formed of a metallic material characterized by properties such as reactivity (i.e., not inert), softness, and a relatively low melting point. For example, the first releasing layer 413 may be formed of metallic materials such as aluminum, tin, or zinc. In some other embodiments, the first releasing layer 413 may be formed of carbon materials such as carbon nanotubes and graphene. Depending on the material used for the first releasing layer 413, the thickness T2 of the first releasing layer 413 may be between about 5 nm and about 400 nm. For example, in one embodiment in which the first releasing layer 413 is formed of a metallic material such as aluminum, the thickness of the first releasing layer 413 is between about 5 nm and about 200 nm. In another embodiment in which the first releasing layer 413 is formed of carbon material, the thickness of the first releasing layer 413 is between about 400 nm or less.

With reference to FIGS. 2 and 4, in some embodiments, where the debonding of the bottom device layer 110 from the first carrier 510 is achieved by laser ablation, the first adhesive layer 411 may be formed of any suitable adhesive material that may or may not be capable of sufficiently absorbing the energy from laser. In some embodiments, the first adhesive layer 411 may be formed of, for example, polymeric adhesive material, high-temperature thermoplastic polyimides, benzocyclobutene, acrylics, epoxies, or other applicable adhesive materials.

Irrespective of the energy absorption ability of the first adhesive layer 411, in some embodiments, the first releasing layer 413 may be configured in material composition and thickness to intensely absorb the energy from laser and serve as a primary releasable layer of the first adhesive structure 410, which is ablated by the laser energy. The first releasing layer 413 may improve the laser ablation efficiency and thus, reduces the ablation threshold of the first adhesive structure 410 (as compared to a bonding structure that uses an adhesive layer alone).

In some embodiments, the first adhesive structure 410 may be fabricated as follows. Initially, the first releasing layer 413 may be formed on a surface of the first carrier 510. For example, the first releasing layer 413 may be formed by depositing a layer of metallic material (e.g., Al) using chemical vapor deposition, physical vapor deposition, or atomic layer deposition. In some other embodiments, the first releasing layer 413 may be formed by growing or otherwise placing a layer of carbon material (e.g., carbon nanotubes, graphene layer, etc.) on a surface of the first carrier 510. A next step may include forming the first adhesive layer 411 on the first releasing layer 413. The first adhesive layer 411 may be formed using known materials and deposition techniques. For example, the first adhesive layer 411 may be formed of any suitable polymeric adhesive material, high-temperature thermoplastic polyimides, benzocyclobutene, acrylics, epoxies, or other applicable adhesive materials. In some embodiments, the first adhesive layer 411 may be formed by spin coating the adhesive material on the first releasing layer 413, and thermally baking the adhesive material to form the first adhesive layer 411. Finally, a standard bonding process may be performed to bond the first carrier 510 (with the first adhesive structure 410) to the back side 110BS of the bottom device layer 110.

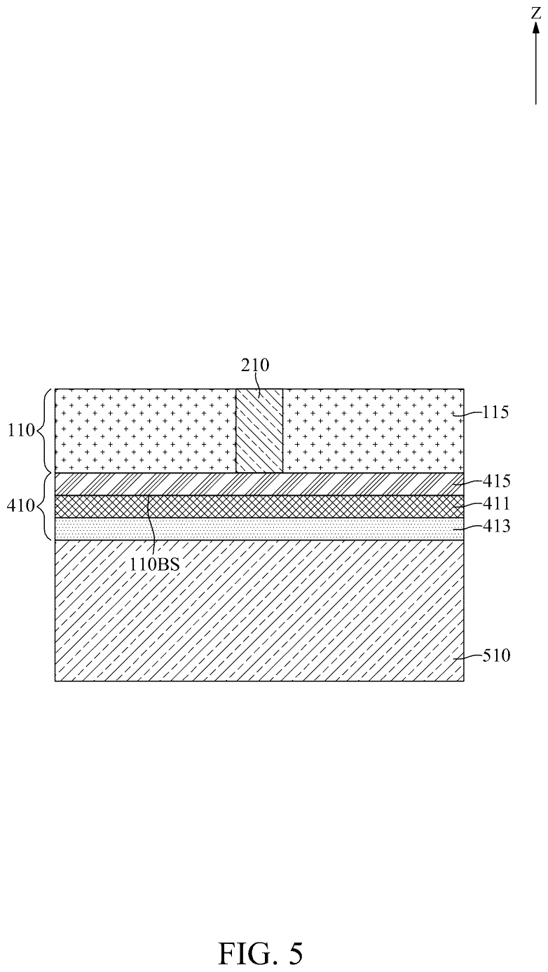

With reference to FIGS. 2 and 5, in some other embodiments, the first adhesive structure 410 may include a first adhesive layer 411, a first releasing layer 413, and a first protection layer 415. The first releasing layer 413 may directly contact the first carrier 510, meaning it is formed on the first carrier 510. The first adhesive layer 411 may be formed on the first releasing layer 413 and disposed between the first releasing layer 413 and the bottom device layer 110. The first protection layer 415 may directly contact the back side 110BS of the bottom device layer 110 and be disposed between the first adhesive layer 411 and the bottom device layer 110, meaning it is disposed underneath the bottom device layer 110.

In some embodiments, the first protection layer 415 may serve to protect the intermediate stack 100 from being irradiated with the energy emitted from the laser during a laser ablation process. Detailedly, the first protection layer 415 may be configured (in material composition and thickness) to reflect incident laser energy away from the intermediate stack 100 back toward the first releasing layer 413. In some embodiments, the first protection layer 415 may be formed of an inert metallic material such as titanium, chromium, gold or copper, with a thickness that is sufficient to reflect the energy. For example, the first protection layer 415 may be formed of a metallic material such as titanium with a thickness in a range of about 50 nm to about 500 nm. In some embodiments, the ablation efficiency of the irradiated portion of the first releasing layer 413 (and adhesive material) in the laser-ablated region may be further enhanced by the additional irradiation reflected back from the first protection layer 415.

In some embodiments, the first adhesive structure 410 in FIG. 5 may be fabricated using similar methods as discussed above with reference to FIG. 4. Initially, the first releasing layer 413 may be formed on a surface of the first carrier 510 followed by forming the first adhesive layer 411 on the first releasing layer 413, using materials and techniques as discussed above with reference to FIG. 4. Next, the first protection layer 415 may be formed on the back side 110BS of the bottom device layer 110 using suitable metallic materials and known deposition techniques. Thereafter, a standard bonding process may be performed to bond the first carrier 510 (with the first adhesive structure 410) to the intermediate stack 100 (with the first protection layer 415) to construct the resulting stack structure.

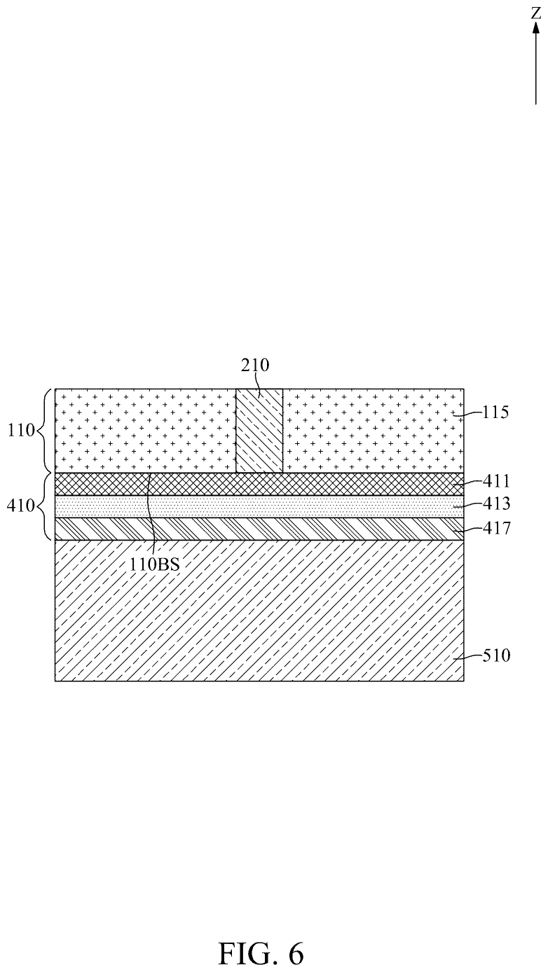

With reference to FIGS. 2 and 6, in some other embodiments, the first adhesive structure 410 may include a first adhesive layer 411, a first releasing layer 413, and a first stress compensation layer 417. The first stress compensation layer 417 may directly contact the first carrier 510, meaning it is formed on the first carrier 510. The first releasing layer 413 may be formed on the first stress compensation layer 417 and disposed between the first stress compensation layer 417 and the bottom device layer 110. The first adhesive layer 411 may directly contact the back side 110BS of the bottom device layer 110 and be disposed between the first releasing layer 413 and the bottom device layer 110, meaning it is disposed underneath the bottom device layer 110. The first stress compensation layer 417 may serve to prevent warping of intermediate stack 100, which can result due to lateral stresses that are applied to the different layers of the intermediate stack 100 during the semiconductor fabrication processing stages.

In some embodiments, the first stress compensation layer 417 may be configured (in material composition and thickness) to counteract stress forces that could otherwise be applied to the layers of the intermediate stack 100 potentially causing the intermediate stack 100 to warp. In addition, the first stress compensation layer 417 may be configured (in material composition and thickness) to be transparent to the wavelength of the laser radiation used in the laser ablation process so that the laser energy will pass through the first stress compensation layer 417 to irradiate the first releasing layer 413. In some embodiments, the first stress compensation layer 417 may be formed of a silicon oxide material (e.g., SiO₂) or a silicon nitride material (e.g., Si₃N₄), for example. The first stress compensation layer 417 may be formed with a thickness in a range of about 100 nm to about 5000 nm, wherein the thickness will depend on the material used and the amount of stress counteraction force needed to prevent warping of the intermediate stack 100. In some embodiments, the first adhesive structure 410 may be fabricated using a similar method as discussed above with reference to FIG. 4. Initially, the first stress compensation layer 417 may be formed on a surface of the first carrier 510, followed by sequentially forming the first releasing layer 413 and the first adhesive layer 411 on the first stress compensation layer 417. Thereafter, a standard bonding process may be performed to bond the first carrier 510 (with the first adhesive structure 410 including the first stress compensation layer 417) to the intermediate stack 100 to construct the resulting stack structure.

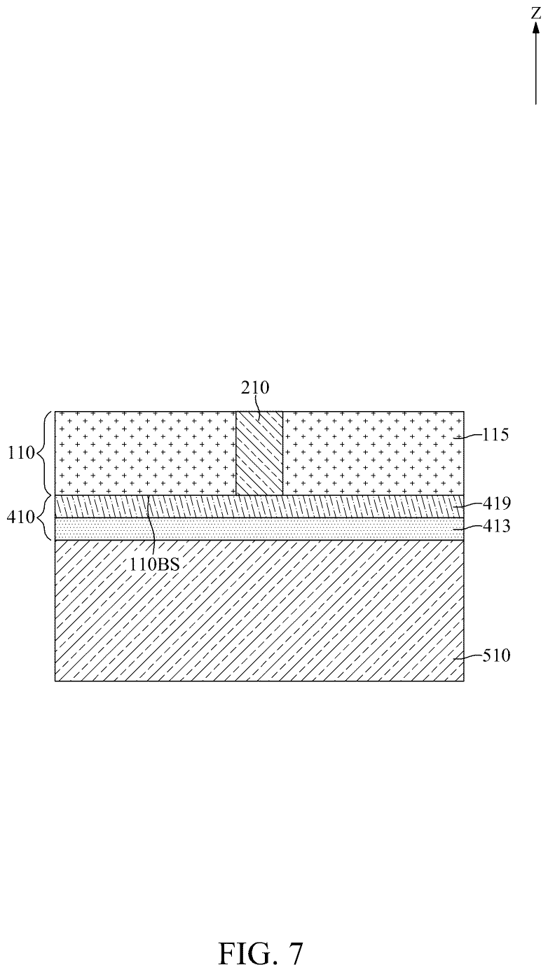

With reference to FIGS. 2 and 7, in some other embodiments, the first adhesive structure 410 may include a first releasing layer 413 and a first reflective adhesive layer 419. The first releasing layer 413 may directly contact the first carrier 510, meaning it is formed on the first carrier 510. The first reflective adhesive layer 419 may directly contact the back side 110BS of the bottom device layer 110 and be disposed between the first releasing layer 413 and the bottom device layer 110, meaning it is disposed underneath the bottom device layer 110. In some embodiments, the first reflective adhesive layer 419 may be formed of a polymer adhesive material, for example, that is premixed with laser energy reflecting particles. The laser energy reflecting particles may include metallic particles (Al, Cu, etc.), or ceramic spheres, and/or other types of nanoparticles such as alumina, boron nitride, silica, etc., which serve to block or otherwise reflect incident radiation. In some embodiments, the first reflective adhesive layer 419 may serve to protect the intermediate stack 100 from radiation. In addition, the first reflective adhesive layer 419 may serve to enhance the ablation efficiency of the first releasing layer 413 in the laser ablated region due to the additional irradiation that is reflected back to the first releasing layer 413 from the first reflective adhesive layer 419, thereby reducing the ablation threshold of the first releasing layer 413.

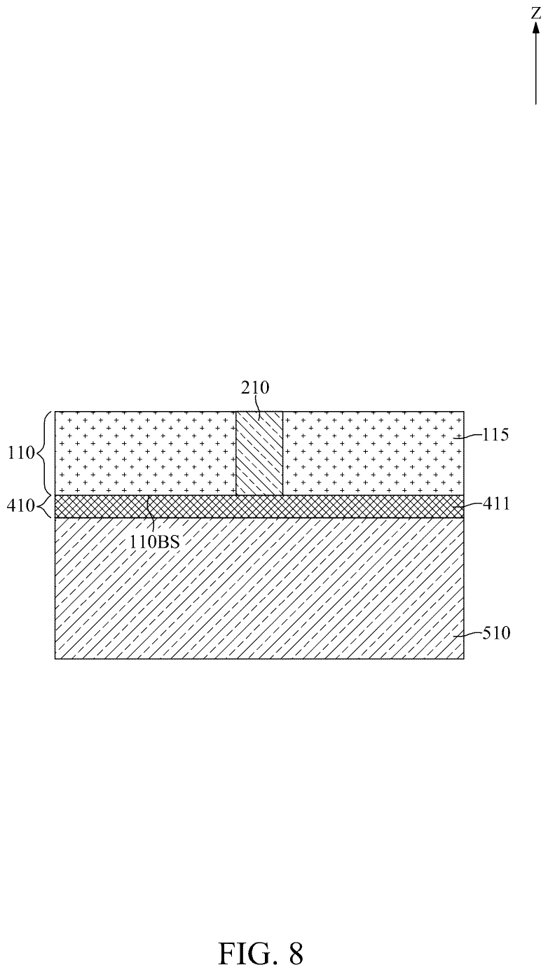

With reference to FIGS. 2 and 8, in some other embodiments, the first adhesive structure 410 may only include a first adhesive layer 411. The first adhesive layer 411 may be a laser energy absorptive adhesive layer. In some embodiments, the first adhesive layer 411 may be formed of a polymer adhesive material that is premixed with metallic nanoparticles that improve the laser energy absorption of the adhesive material. For example, the nanoparticles may be formed of Sn, Zn, Al, carbon nanotubes or graphene, or a combination thereof. The first adhesive layer 411 may be formed by a deposition coating process, such as spin coating or spray coating, or some other alternate form of deposition coating known in the art (or any combination of deposition coating processes), wherein the polymer adhesive material with the premixed metallic nanoparticles is deposition coated onto the surface of the first carrier 510 before bonding to the intermediate stack 100. The first adhesive layer 411 may serve as a release layer of laser ablation.

In some embodiments, the first adhesive layer 411 may function as a release layer and may include materials with low melting points or glass transition temperatures, allowing their viscosity to decrease and become fluid when heated to a specific temperature (e.g., their respective melting points or glass transition temperatures). For example, the first adhesive layer 411 may include propylene carbonate, polyurethane, polypropylene carbonate, or HT series materials (available from Brewer Science).

In some embodiments, the first adhesive layer 411 may be formed of materials that are dissolvable in solvents. For example, the first adhesive layer 411 may include a thermosetting resin produced by the polycondensation of methyl diamine and aldehydes, polyisobutylene (PIB) rubber, or Oppanol® (available from BASF).

In some other embodiments, the first carrier 510 may directly contact the back side 110BS of the bottom device layer 110. That is the first adhesive structure 410 may be omitted.

With reference back to FIG. 2, the opening OP1 may be formed in the passivation layer 147. The topmost conductive feature 149 may be exposed through the opening OP1. The chip probing process may be performed using the corresponding conductive feature 149 through the opening OP1 to examine the electrical characteristics of the intermediate stack 100.

With reference to FIG. 9, the opening OP1 may be filled after the chip probing process. A planarization process, such as chemical mechanical polishing, may be performed to remove excess material and provide a substantially flat surface for subsequent processing steps.

In some other embodiments, the intermediate stack 100 may include only one intermediate device layer 120 (not shown in figures). The intermediate device layer 120 may be disposed between the bottom device layer 110 and the surface device layer 140.

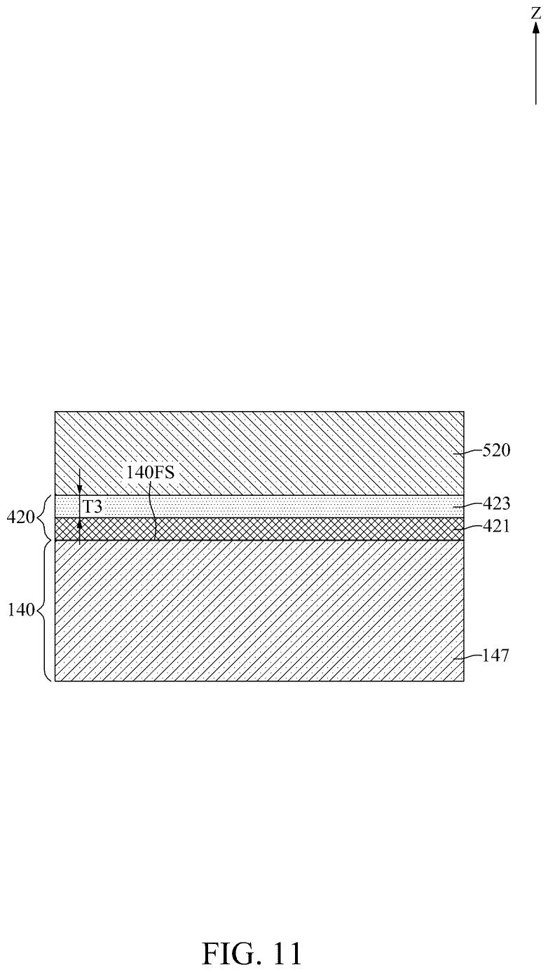

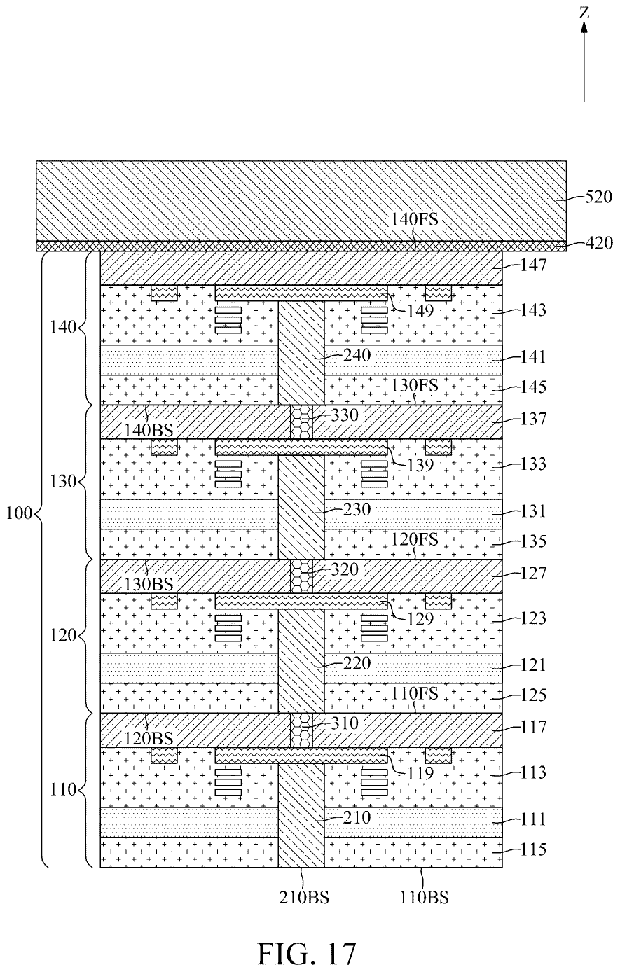

FIGS. 11 to 16 illustrate, in schematic close-up diagrams, second adhesive structures in accordance with some embodiment of the present disclosure. FIGS. 17 to 19 illustrate, in schematic cross-sectional view diagrams, intermediate stages for fabricating the semiconductor device stack 1 in accordance with one embodiment of the present disclosure.

With reference to FIG. 1, and FIGS. 10 to 16, at step S13, a second carrier 520 may be bonded onto the intermediate stack 100.

With reference to FIG. 10, the second carrier 520 may be bonded on the intermediate stack 100. In some embodiments, the second carrier 520 may be formed of the same material as the first carrier 510. In some embodiments, the second carrier 520 may be formed of a different material from the first carrier 510. The separation process used to detach the intermediate stack 100 from the second carrier 520 may differ from the separation process used for detaching it from the first carrier 510. In some embodiments, the second carrier 520 may be a dummy wafer which is used for temporary support of structures attached to it and does not include any permanently integrated functional units. In some embodiments, the second carrier 520 may be from of silicon, glass, polymer, sapphire, or other suitable substrates. In some embodiments, the second carrier 520 may also be a thick dielectric layer that can be removed by grinding in subsequent processes. This dielectric layer may include materials such as silicon oxide, borophosphosilicate glass, undoped silicate glass, fluorinated silicate glass, silicon nitride, silicon oxynitride, silicon nitride oxide, or other appropriate dielectric materials. In some embodiments, the thickness of the dielectric layer may be greater than 500 μm.

In some embodiments, the second carrier 520 may be bonded onto the front side 140FS of the surface device layer 140 via a second adhesive structure 420 formed therebetween. In some embodiments, the second adhesive structure 420 may include materials that are resistant to acids, alkalis, and high temperatures to ensure stability during backside processes such as curing, grinding, etching, and metallization, prior to debonding the intermediate stack 100 from the second carrier 520.

With reference to FIGS. 10 and 11, the second adhesive structure 420 may be disposed between the second carrier 520 and the surface device layer 140. In some embodiments, the second adhesive structure 420 may include a second adhesive layer 421 and a second releasing layer 423. The second releasing layer 423 may directly contact the second carrier 520, meaning it is disposed underneath the second carrier 520. The second adhesive layer 421 may directly contact the front side 140FS of the surface device layer 140 and between the second releasing layer 423 and the surface device layer 140, meaning it is disposed on the surface device layer 140.

In some embodiments, the second releasing layer 423 may be removed during a subsequent process via thermal slide debonding, chemical dissolution, mechanical peel-off, or laser ablation, thereby enabling debonding of the surface device layer 140 from the second carrier 520.

In some embodiments, where the debonding of the surface device layer 140 from the second carrier 520 is achieved by laser ablation, the second releasing layer 423 may be formed of a metallic material characterized by properties such as reactivity (i.e., not inert), softness, and a relatively low melting point. For example, the second releasing layer 423 may be formed of metallic materials such as aluminum, tin, or zinc. In some other embodiments, the second releasing layer 423 may be formed of carbon materials such as carbon nanotubes and graphene. Depending on the material used for the second releasing layer 423, the thickness T3 of the second releasing layer 423 may be between about 5 nm and about 400 nm. For example, in one embodiment in which the second releasing layer 423 is formed of a metallic material such as aluminum, the thickness of the second releasing layer 423 is between about 5 nm and about 200 nm. In another embodiment in which the second releasing layer 423 is formed of carbon material, the thickness of the second releasing layer 423 is between about 400 nm or less.

With reference to FIGS. 10 and 11, in some embodiments, where the debonding of the surface device layer 140 from the second carrier 520 is achieved by laser ablation, the second adhesive layer 421 may be formed of any suitable adhesive material that may or may not be capable of sufficiently absorbing the energy from laser. In some embodiments, the second adhesive layer 421 may be formed of, for example, polymeric adhesive material, high-temperature thermoplastic polyimides, benzocyclobutene, acrylics, epoxies, or other applicable adhesive materials.

Irrespective of the energy absorption ability of the second adhesive layer 421, in some embodiments, the second releasing layer 423 may be configured in material composition and thickness to intensely absorb the energy from laser and serve as a primary releasable layer of the second adhesive structure 420, which is ablated by the laser energy. The second releasing layer 423 may improve the laser ablation efficiency and thus, reduces the ablation threshold of the second adhesive structure 420 (as compared to a bonding structure that uses an adhesive layer alone).

In some embodiments, the second adhesive structure 420 may be fabricated as follows. Initially, the second releasing layer 423 may be formed on a surface of the second carrier 520. For example, the second releasing layer 423 may be formed by depositing a layer of metallic material (e.g., Al) using chemical vapor deposition, physical vapor deposition, or atomic layer deposition. In some other embodiments, the second releasing layer 423 may be formed by growing or otherwise placing a layer of carbon material (e.g., carbon nanotubes, graphene layer, etc.) on a surface of the second carrier 520. A next step may include forming the second adhesive layer 421 on the second releasing layer 423. The second adhesive layer 421 may be formed using known materials and deposition techniques. For example, the second adhesive layer 421 may be formed of any suitable polymeric adhesive material, high-temperature thermoplastic polyimides, benzocyclobutene, acrylics, epoxies, or other applicable adhesive materials. In some embodiments, the second adhesive layer 421 may be formed by spin coating the adhesive material on the second releasing layer 423, and thermally baking the adhesive material to form the second adhesive layer 421. Finally, a standard bonding process may be performed to bond the second carrier 520 (with the second adhesive structure 420) to the front side 140FS of the surface device layer 140.

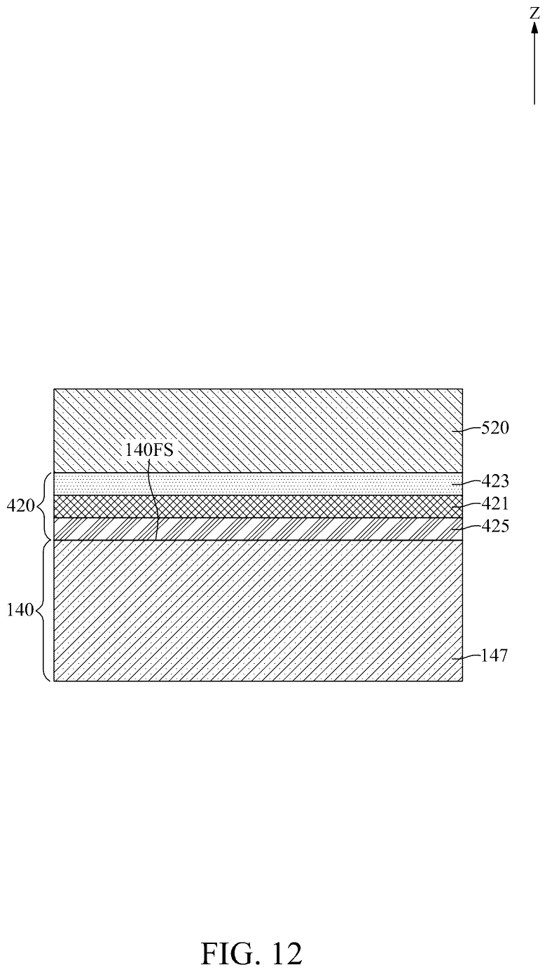

With reference to FIGS. 10 and 12, in some other embodiments, the second adhesive structure 420 may include a second adhesive layer 421, a second releasing layer 423, and a second protection layer 425. The second releasing layer 423 may directly contact the second carrier 520, meaning it is formed underneath the second carrier 520. The second adhesive layer 421 may be formed underneath the second releasing layer 423 and disposed between the second releasing layer 423 and the surface device layer 140. The second protection layer 425 may directly contact the front side 140FS of the surface device layer 140 and be disposed between the second adhesive layer 421 and the surface device layer 140, meaning it is disposed on the surface device layer 140.

In some embodiments, the second protection layer 425 may serve to protect the intermediate stack 100 from being irradiated with the energy emitted from the laser during a laser ablation process. Detailedly, the second protection layer 425 may be configured (in material composition and thickness) to reflect incident laser energy away from the intermediate stack 100 back toward the second releasing layer 423. In some embodiments, the second protection layer 425 may be formed of an inert metallic material such as titanium, chromium, gold or copper, with a thickness that is sufficient to reflect the energy. For example, the first protection layer 415 may be formed of a metallic material such as titanium with a thickness in a range of about 50 nm to about 500 nm. In some embodiments, the ablation efficiency of the irradiated portion of the second releasing layer 423 (and adhesive material) in the laser-ablated region may be further enhanced by the additional irradiation reflected back from the second protection layer 425.

In some embodiments, the second adhesive structure 420 in FIG. 12 may be fabricated using similar methods as discussed above with reference to FIG. 11. Initially, the second releasing layer 423 may be formed on a surface of the second carrier 520 followed by forming the second adhesive layer 421 on the second releasing layer 423, using materials and techniques as discuss above with reference to FIG. 11. Next, the second protection layer 425 may be formed on the front side 140FS of the surface device layer 140 using suitable metallic materials and known deposition techniques. Thereafter, a standard bonding process may be performed to bond the second carrier 520 (with the second adhesive structure 420) to the intermediate stack 100 (with the second protection layer 425) to construct the resulting stack structure.

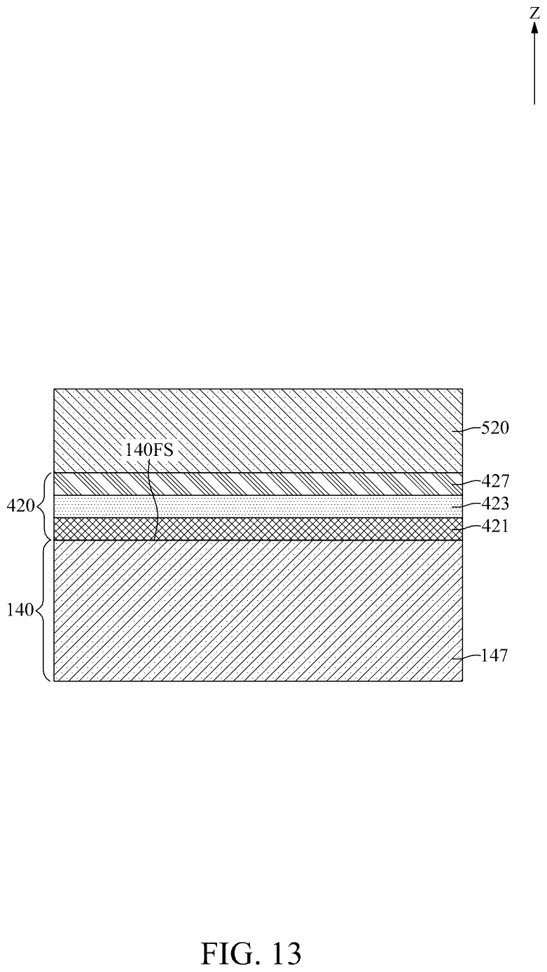

With reference to FIGS. 10 and 13, in some other embodiments, the second adhesive structure 420 may include a second adhesive layer 421, a second releasing layer 423, and a second stress compensation layer 427. The second stress compensation layer 427 may directly contact the second carrier 520, meaning it is formed underneath the second carrier 520. The second releasing layer 423 may be formed underneath the second stress compensation layer 427 and disposed between the second stress compensation layer 427 and the surface device layer 140. The second adhesive layer 421 may directly contact the front side 140FS of the surface device layer 140 and be disposed between the second releasing layer 423 and the surface device layer 140, meaning it is disposed on the surface device layer 140. The second stress compensation layer 427 may serve to prevent warping of intermediate stack 100, which can result due to lateral stresses that are applied to the different layers of the intermediate stack 100 during the semiconductor fabrication processing stages.

In some embodiments, the second stress compensation layer 427 may be configured (in material composition and thickness) to counteract stress forces that could otherwise be applied to the layers of the intermediate stack 100 potentially causing the intermediate stack 100 to warp. In addition, the second stress compensation layer 427 may be configured (in material composition and thickness) to be transparent to the wavelength of the laser radiation used in the laser ablation process so that the laser energy will pass through the second stress compensation layer 427 to irradiate the second releasing layer 423. In some embodiments, the second stress compensation layer 427 may be formed of a silicon oxide material (e.g., SiO₂) or a silicon nitride material (e.g., Si₃N₄), for example. The second stress compensation layer 427 may be formed with a thickness in a range of about 100 nm to about 5000 nm, wherein the thickness will depend on the material used and the amount of stress counteraction force needed to prevent warping of the intermediate stack 100. In some embodiments, the second adhesive structure 420 may be fabricated using a similar method as discussed above with reference to FIG. 11. Initially, the second stress compensation layer 427 may be formed on a surface of the second carrier 520, followed by sequentially forming the second releasing layer 423 and the second adhesive layer 421 on the second stress compensation layer 427. Thereafter, a standard bonding process may be performed to bond the second carrier 520 (with the second adhesive structure 420 including the second stress compensation layer 427) to the intermediate stack 100 to construct the resulting stack structure.

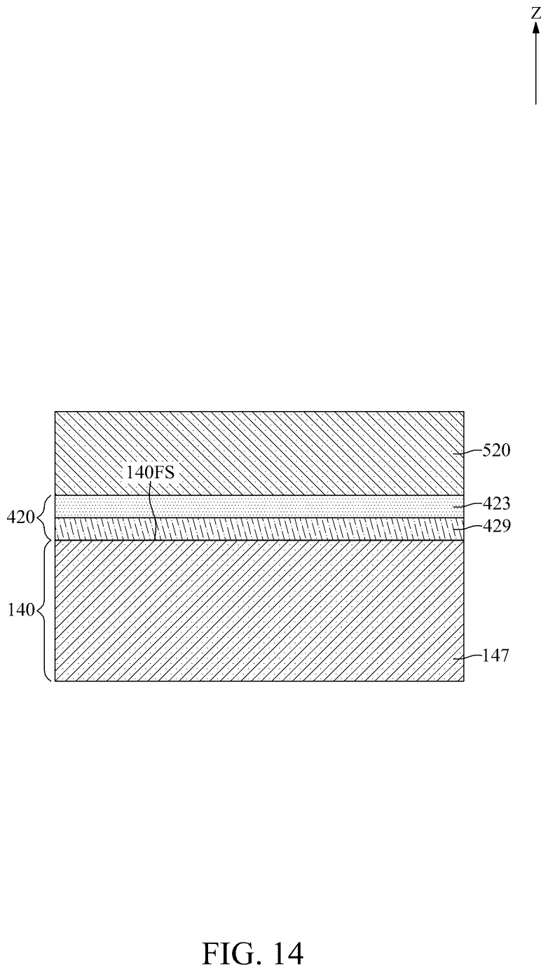

With reference to FIGS. 10 and 14, in some other embodiments, the second adhesive structure 420 may include a second releasing layer 423 and a second reflective adhesive layer 429. The second releasing layer 423 may directly contact the second carrier 520, meaning it is formed underneath the second carrier 520. The second reflective adhesive layer 429 may directly contact the front side 140FS of the surface device layer 140 and be disposed between the second releasing layer 423 and the surface device layer 140, meaning it is disposed on the surface device layer 140. In some embodiments, the second reflective adhesive layer 429 may be formed of a polymer adhesive material, for example, that is premixed with laser energy reflecting particles. The laser energy reflecting particles may include metallic particles (Al, Cu, etc.), or ceramic spheres, and/or other types of nanoparticles such as alumina, boron nitride, silica, etc., which serve to block or otherwise reflect incident radiation. In some embodiments, the second reflective adhesive layer 429 may serve to protect the intermediate stack 100 from radiation. In addition, the second reflective adhesive layer 429 may serve to enhance the ablation efficiency of the second releasing layer 423 in the laser ablated region due to the additional irradiation that is reflected back to the second releasing layer 423 from the second reflective adhesive layer 429, thereby reducing the ablation threshold of the second releasing layer 423.

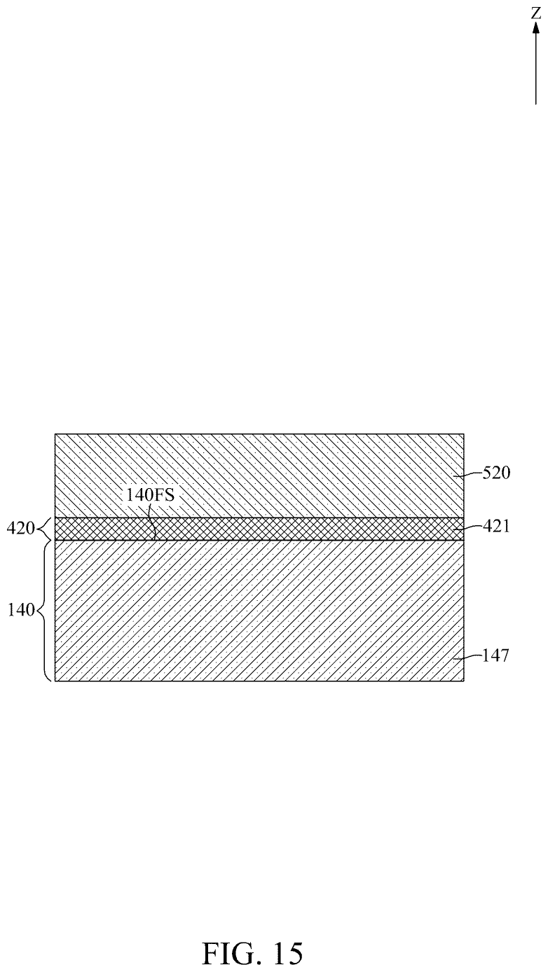

With reference to FIGS. 10 and 15, in some other embodiments, the second adhesive structure 420 may only include a second adhesive layer 421. The second adhesive layer 421 may be a laser energy absorptive adhesive layer. In some embodiments, the second adhesive layer 421 may be formed of a polymer adhesive material that is premixed with metallic nanoparticles that improve the laser energy absorption of the adhesive material. For example, the nanoparticles may be formed of Sn, Zn, Al, carbon nanotubes or graphene, or a combination thereof. The second adhesive layer 421 may be formed by a deposition coating process, such as spin coating or spray coating, or some other alternate form of deposition coating known in the art (or any combination of deposition coating processes), wherein the polymer adhesive material with the premixed metallic nanoparticles is deposition coated onto the surface of the second carrier 520 before bonding to the intermediate stack 100. The second adhesive layer 421 may serve as a release layer of laser ablation.

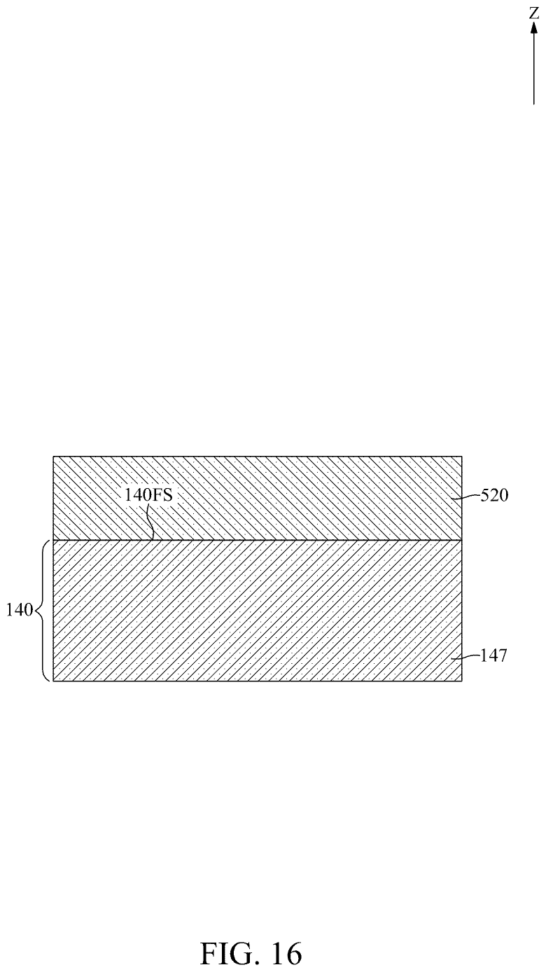

With reference to FIGS. 10 and 16, in some other embodiments, the second adhesive structure 420 may be omitted. That is, the second carrier 520 may directly contact the front side 140FS of the surface device layer 140. The second carrier 520 and the passivation layer 147 of the surface device layer 140 may be bonded through a fusion bonding process. A surface treatment such as plasma treatment for the second carrier 520 and the surface device layer 140 may be performed before the fusion bonding process. An annealing process may be performed after the fusion bonding process. The process temperature of the annealing process may be between about 800 °C and about 1100 °C.

With reference to FIGS. 1 and 17, at step S15, the first carrier 510 may be removed from the intermediate stack 100.

With reference to FIG. 17, in some embodiments, the first carrier 510 may be removed by a grinding process. In some embodiments, the abrasive material for the grinding process may be, for example, silicon carbide, diamond, or other applicable materials.

In some embodiments, a cleaning process may be performed to remove the first adhesive structure 410 (if exist) after the grinding process. In some embodiments, the cleaning process may be, for example, a wet etching process.

In some other embodiments, the first carrier 510 may be removed by a debonding process. The debonding process may include thermal slide debonding, chemical dissolution, mechanical peel-off, or laser ablation.

In some embodiments, the thermal slide debonding may involve heating a thermoplastic adhesive layer (e.g., the first adhesive structure 410) to reduce its viscosity, allowing the intermediate stack 100 to slide apart. The process temperature of thermal slide debonding may be between about 150 °C and about 190 °C, softening the polymer to enable separation with minimal mechanical stress.

In some embodiments, chemical dissolution may rely on solvents to dissolve temporary bonding adhesives (e.g., the first adhesive structure 410). In some embodiments, the solvents used for chemical dissolution may include sulfuric acid, hexane, or 1-dodecene.

In some embodiments, mechanical peel-off may be used to separate the first carrier 510 from the intermediate stack 100 through the application of controlled physical force. A blade or air jet may initiate the separation, which is then propagated by a programmable roller to complete the debonding process.

In some embodiments, the laser ablation debonding process may employ ultraviolet (e.g., 308 nm, 355 nm) or mid-infrared lasers (radiation) to selectively degrade the light-absorbing first releasing layer 413. The laser energy may vaporize the first releasing layer 413, thereby enabling separation of the intermediate stack 100 from the first carrier 510. In some embodiments, the wavelength of the mid-infrared lasers may be between about 1.12 μm and about 5 μm, or about 1.12 μm and about 3 μm. The laser ablation process using mid-infrared radiation may be compatible with carriers made of either silicon or glass, and may also be suitable for use with stress compensation layers.

In some embodiments, a cleaning process may be performed to remove the remaining first adhesive structure 410 after the debonding process. In some embodiments, the cleaning process may be, for example, a wet etching process.

In some other embodiments, after the debonding process, the intermediate stack 100 may not be immediately subjected to any adhesive removal process, and the first adhesive layer 411 may remain on the back side 110BS of the bottom device layer 110. As a result, the residual first adhesive layer 411 can protect the bonding interface on the back side 110BS from contamination during subsequent processing steps. In particular, it can help prevent oxidation of metal regions at the bonding interface (e.g., the bottom surface 210BS of the bottom through-substrate via 210) caused by air exposure. This protective role of the remaining first adhesive structure 410 may also extend the allowable waiting time before bonding another device layer—such as the functional device layer 600, to be described later—to the intermediate stack 100.

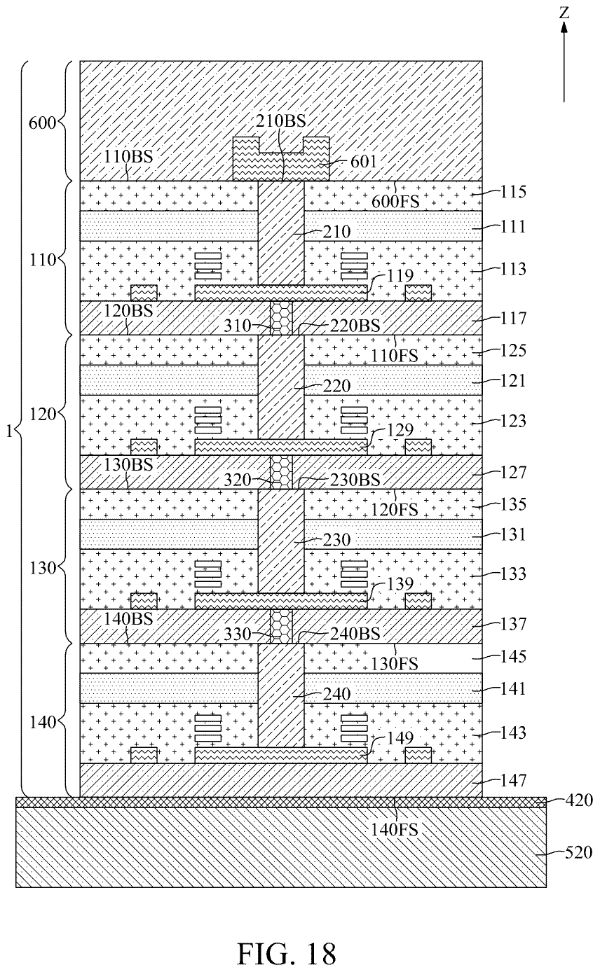

With reference to FIGS. 1 and 18, at step S17, the intermediate stack 100 may be flipped and a functional device layer 600 may be bonded onto the bottom device layer 110 of the intermediate stack 100 to configure a semiconductor device stack 1.

With reference to FIG. 18, the intermediate stack 100, along with the second carrier 520, may be flipped such that the back side 110BS of the bottom device layer 110 faces upward.

The front side 600FS of the functional device layer 600 may be bonded onto the back side 110BS of the bottom device layer 110 through a bonding process. In other words, the functional device layer 600 and the intermediate stack 100 may be bonded in a face to back configuration. The bonding process may include a thermal treatment performed to achieve a hybrid bonding between elements of the functional device layer 600 and the bottom device layer 110. The hybrid bonding may include a dielectric-to-dielectric bonding and a metal-to-metal bonding. The dielectric-to-dielectric bonding may originate from the bonding between the dielectric layer (or passivation layer) of the functional device layer 600 and the passivation layer 147 of the bottom device layer 110. The metal-to-metal bonding may originate from the bonding between the conductive features 601 of the functional device layer 600 and bottom through substrate via 210. The temperature of the bonding process may be between about 300 °C and about 450 °C.

In some embodiments, the functional device layer 600 may be an application-specific integrated circuit (ASIC). It may include circuits for various functions, such as buffering, repair operations, global memory refresh management, mode register settings, power network optimization, memory built-in self-test (MBIST), training, trimming, fusing or adjustment circuits (for one-time programming), programmable registers, and/or feature selection or configuration functionalities. The device layers 110, 120, 130, and 140 of the intermediate stack 100 may include circuits such as memory arrays, decoders, multiplexers, buffers, and/or amplifiers. In some embodiments, the functional device layer 600 and the intermediate stack 100 may together form a high-bandwidth memory (HBM) system.

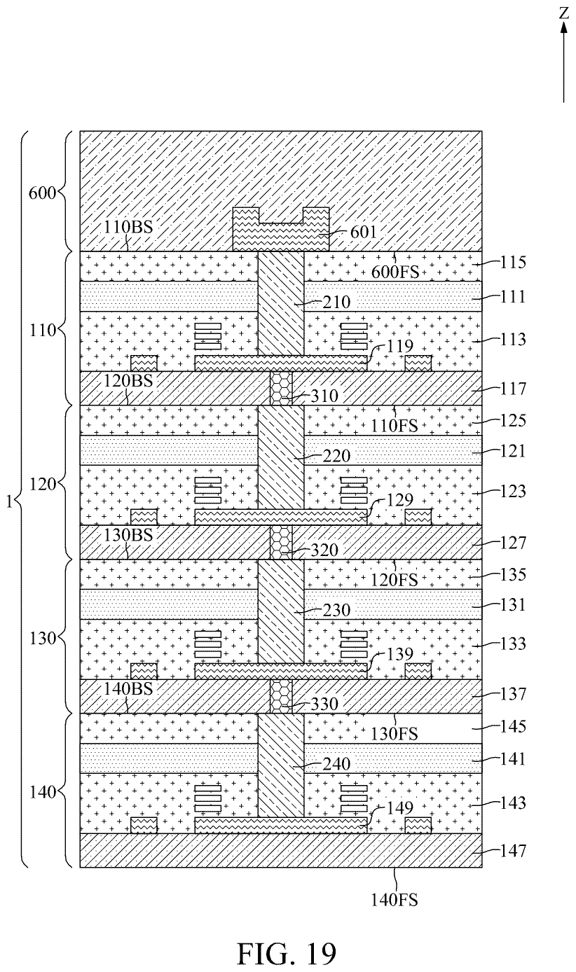

With reference to FIG. 1 and FIG. 19, at step S19, the second carrier 520 may be removed.

With reference to FIG. 19, in some embodiments, the second carrier 520 may be removed by a grinding process. In some embodiments, the abrasive material for the grinding process may be, for example, silicon carbide, diamond, or other applicable materials.

In some embodiments, a cleaning process may be performed to remove the second adhesive structure 420 (if exist) after the grinding process. In some embodiments, the cleaning process may be, for example, a wet etching process.

In some other embodiments, the second carrier 520 may be removed by a debonding process. The debonding process may include thermal slide debonding, chemical dissolution, mechanical peel-off, or laser ablation.

In some embodiments, the thermal slide debonding may involve heating a thermoplastic adhesive layer (e.g., the second adhesive structure 420) to reduce its viscosity, allowing the intermediate stack 100 to slide apart. The process temperature of thermal slide debonding may be between about 150 °C and about 190 °C, softening the polymer to enable separation with minimal mechanical stress.

In some embodiments, chemical dissolution may rely on solvents to dissolve temporary bonding adhesives (e.g., the second adhesive structure 420). In some embodiments, the solvents used for chemical dissolution may include sulfuric acid, hexane, or 1-dodecene.

In some embodiments, mechanical peel-off may be used to separate the second carrier 520 from the intermediate stack 100 through the application of controlled physical force. A blade or air jet may initiate the separation, which is then propagated by a programmable roller to complete the debonding process.

In some embodiments, the laser ablation debonding process may employ ultraviolet (e.g., 308 nm, 355 nm) or mid-infrared lasers (radiation) to selectively degrade the light-absorbing second releasing layer 423. The laser energy may vaporize the second releasing layer 423, thereby enabling separation of the intermediate stack 100 from the second carrier 520. In some embodiments, the wavelength of the mid-infrared lasers may be between about 1.12 μm and about 5 μm, or about 1.12 μm and about 3 μm. The laser ablation process using mid-infrared radiation may be compatible with carriers made of either silicon or glass, and may also be suitable for use with stress compensation layers.

In some embodiments, a cleaning process may be performed to remove the remaining second adhesive structure 420 after the debonding process. In some embodiments, the cleaning process may be, for example, a wet etching process.

In some other embodiments, after the debonding process, the intermediate stack 100 may not be immediately subjected to any adhesive removal process, and the second adhesive structure 420 may remain on the front side 140FS of the surface device layer 140. As a result, the residual second adhesive layer 421 can protect the bonding interface on the front side 140FS from contamination during subsequent processing steps. This protective role of the remaining second adhesive structure 420 may also extend the allowable waiting time before bonding another device layer to the intermediate stack 100.

One aspect of the present disclosure provides a semiconductor device stack including a bottom device layer, at least one intermediate device layer, and a surface device layer sequentially stacked; a bottom through substrate via positioned in the bottom device layer and a bottom surface of the bottom through substrate via is coplanar with a back side of the bottom device layer; at least one intermediate through substrate via positioned in the at least one intermediate device layer and a bottom surface of the at least one intermediate through substrate via is coplanar with a back side of the at least one intermediate device layer contacting the bottom device layer; a surface through substrate via positioned in the surface device layer and a bottom surface of the surface through substrate via is coplanar with a back side of the surface device layer contacting the at least one intermediate device layer; a plurality of inter-layered connection vias electrically connecting the bottom through substrate via and the at least one intermediate device layer, and electrically connecting the surface through substrate via and the at least one intermediate device layer, respectively; a first carrier contacting the back side of the bottom device layer and covering the bottom through substrate via; and a second carrier covering a front side of the surface device layer.

Another aspect of the present disclosure provides a semiconductor device stack including a bottom device layer, at least one intermediate device layer, and a surface device layer sequentially stacked; a bottom through substrate via positioned in the bottom device layer and a bottom surface of the bottom through substrate via is coplanar with a back side of the bottom device layer; at least one intermediate through substrate via positioned in the at least one intermediate device layer and a bottom surface of the at least one intermediate through substrate via is coplanar with a back side of the at least one intermediate device layer contacting the bottom device layer; a surface through substrate via positioned in the surface device layer and a bottom surface of the surface through substrate via is coplanar with a back side of the surface device layer contacting the at least one intermediate device layer; a plurality of inter-layered connection vias electrically connecting the bottom through substrate via and the at least one intermediate device layer, and electrically connecting the surface through substrate via and the at least one intermediate device layer, respectively; a front side of a functional device layer positioned on the back side of the bottom device layer; and a second carrier covering a front side of the surface device layer.

Another aspect of the present disclosure provides a method for fabricating a semiconductor device stack including providing an intermediate stack including a bottom device layer, at least one intermediate device layer, and a surface device layer sequentially stacked, and a bottom through substrate via in the bottom device layer, wherein a bottom surface of the bottom through substrate via is coplanar with a back side of the bottom device layer; forming a first carrier covering the back side of the bottom device layer and the bottom surface of the bottom through substrate via; performing a chip probing process through an opening of the surface device layer and filling the opening; forming a second carrier covering a front side of the surface device layer; separating the intermediate stack from the first carrier; and flipping the intermediate stack and bonding a functional device layer onto the back side of the bottom device layer.

Due to the design of the semiconductor device stack 1 of the present disclosure, the induced parasitic inductance arising from dangling (or floating) bottom through substrate via 210 may be avoided by bonding the functional device layer 600 onto the bottom through substrate via 210 with the support of the second carrier 520. As a result, the performance of the semiconductor device stack 1 may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for fabricating a semiconductor device stack, comprising:
providing an intermediate stack comprising a bottom device layer, at least one intermediate device layer, and a surface device layer sequentially stacked, and a bottom through substrate via in the bottom device layer, wherein a bottom surface of the bottom through substrate via is coplanar with a back side of the bottom device layer;
forming a first carrier covering the back side of the bottom device layer and the bottom surface of the bottom through substrate via;
performing a chip probing process through an opening of the surface device layer and filling the opening;
forming a second carrier covering a front side of the surface device layer;
separating the intermediate stack from the first carrier; and
flipping the intermediate stack and bonding a functional device layer onto the back side of the bottom device layer.

2. The method for fabricating the semiconductor device stack of claim 1, further comprising separating the surface device layer from the second carrier.

3. The method for fabricating the semiconductor device stack of claim 1, wherein the first carrier and the second carrier comprise the same material.

4. The method for fabricating the semiconductor device stack of claim 1, wherein the first carrier and the second carrier comprise different materials.

5. The method for fabricating the semiconductor device stack of claim 1, wherein the second carrier is formed on the surface device layer through a fusion bonding process.

6. The method for fabricating the semiconductor device stack of claim 1, wherein the functional device layer is bonded onto the bottom device layer through a hybrid bonding process.

7. The method for fabricating the semiconductor device stack of claim 1, wherein separating the intermediate stack from the first carrier is achieved by grinding.

8. The method for fabricating the semiconductor device stack of claim 2, wherein separating the surface device layer from the second carrier is achieved by grinding.

9. The method for fabricating the semiconductor device stack of claim 1, wherein a first adhesive structure is formed between the first carrier and the bottom device layer.

10. The method for fabricating the semiconductor device stack of claim 9, wherein separating the intermediate stack from the first carrier is achieved by thermal slide debonding, chemical dissolution, mechanical peel-off, or laser ablation.

11. The method for fabricating the semiconductor device stack of claim 9, wherein the first adhesive structure comprises a first releasing layer formed between the first carrier and the bottom device layer, and a first adhesive layer formed between the first releasing layer and the bottom device layer.

12. The method for fabricating the semiconductor device stack of claim 11, wherein the first releasing layer comprises aluminum, tin, or zinc.

13. The method for fabricating the semiconductor device stack of claim 11, wherein the first releasing layer comprises carbon nanotubes and graphene.

14. The method for fabricating the semiconductor device stack of claim 1, wherein the first carrier comprises silicon oxide, borophosphosilicate glass, undoped silicate glass, fluorinated silicate glass, silicon nitride, silicon oxynitride, or silicon nitride oxide.

15. The method for fabricating the semiconductor device stack of claim 1, wherein the first carrier comprises silicon, glass, polymer, or sapphire.
